(19) United States
(12) Patent Application Publication
(10) Pub. No.: US 2025/0212521 A1
(43) Pub. Date: Jun. 26, 2025

(54) SYSTEMS AND METHODS FOR PIXEL DISAGGREGATION

(71) Applicant: Meta Platforms Technologies, LLC, Menlo Park, CA (US)

(72) Inventors: William Anthony Smith, Carnation, WA (US); Michael Yee, Woodinville, WA (US); Brad Bartley, Denver, CO (US); Daniel Henry Morris, Mountain View, CA (US)

(21) Appl. No.: 18/390,977

(22) Filed: Dec. 20, 2023

(51) Int. Cl. H01L 27/12; H01L 27/15

(52) U.S. Cl. CPC H10D 87/00; H10D 86/0221; H10D 86/441; H10D 86/60; H10H 29/142

(57) ABSTRACT

A method for pixel disaggregation can include forming a first layer of semiconductor material, wherein the first layer of semiconductor material includes memory and logic devices of a semiconductor device and is configured as a digital backplane that controls a plurality of analog devices of the semiconductor device. The method can additionally include forming a second layer of semiconductor material stacked atop the first layer of semiconductor material, wherein the second layer of semiconductor material includes the plurality of analog devices of the semiconductor device and is configured generate a per-pixel bias in response to control by the digital backplane. Various other methods, systems, and computer-readable media are also disclosed.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for pixel disaggregation.

FIG. 2 is an illustration of example semiconductor devices.

FIG. 3 is an illustration of an example semiconductor device for pixel disaggregation.

FIG. 4 is an illustration of an example semiconductor device for pixel disaggregation.

FIG. 5 is an illustration of example portions of layers of semiconductor devices configured as inner tiles.

FIG. 6 is an illustration of example portions of layers of semiconductor devices configured as inner tiles.

FIG. 7 is an illustration of example semiconductor device packages for pixel disaggregation.

FIG. 8 is an illustration of exemplary augmented-reality glasses that may be used in connection with embodiments of this disclosure.

FIG. 9 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Semiconductor display devices may be used in various applications, such as artificial reality. Such devices may include a bezel surrounding a pixel array. various devices, such as memory, logic devices, and/or analog devices. Example memory and logic devices may be configured to perform digital data communication, global timing control, pattern generation, calibration control, pixel-level timing control, local calibration data storage, and/or local reprojection. Example analog devices may include cathode contacts, analog controllers, temperature sensors, current sources, pulse width modulation switches, and/or instruction/address decoders. Form factor and/or optical performance of such devices may be impacted by inclusion of the bezel.

The present disclosure is generally directed to systems and methods for pixel disaggregation. For example, by stacking layers of semiconductor material, circuit elements (e.g., memory, logic, and/or analog devices) of a semiconductor device that would otherwise occupy a periphery (e.g., bezel) of the semiconductor device may be relocated to one or more of the layers, both reducing an area and improving performance of the semiconductor device. In one example, a first layer of semiconductor material may include memory and logic devices of the semiconductor device and be configured as a digital backplane that controls a plurality of analog devices of the semiconductor device. In this example, a second layer of semiconductor material may be stacked atop the first layer of semiconductor material, and the second layer of semiconductor material may include the plurality of analog devices of the semiconductor device and be configured to generate a per-pixel bias in response to control by the digital backplane.

The disclosed systems and methods may yield numerous benefits. For example, optical form factor may be improved by relocating analog devices to a stacked layer of a semiconductor device, thus removing or reducing a bezel of the device, which improves optical performance of the semiconductor device and reduces the area of the semiconductor device. Additionally, 3D stacking may yield shorter power and/or signal pathways that experience reduced current drop. Also, 3D stacking that disaggregates analog and digital circuit elements into different semiconductor layers allows a layer containing the digital elements to be constructed according to a more advanced technology (e.g., smaller circuit elements) compared to another layer containing the analog circuit elements, thus achieving additional compute capability for the digital circuit elements without incurring increased costs for the analog circuit elements. As a result, local translation may be improved by providing additional compute capability in a backplane, thus achieving high-frequency translation of objects based on eye position. Further, optical performance may be improved by providing a pulse-based, high duty cycle (e.g., 10 kilohertz) display and/or by achieving improved pixel performance, such as higher bit depth, improved current source accuracy, and/or additional calibration points for temperature, aging, etc. Further, the disclosed systems and methods offer an option to eliminate negative supply rails for common-cathode configuration and/or provide a potential solution for green-blue display applications. Finally, the 3-D stacking implementation may achieve pixel pitches of less than two micrometers.

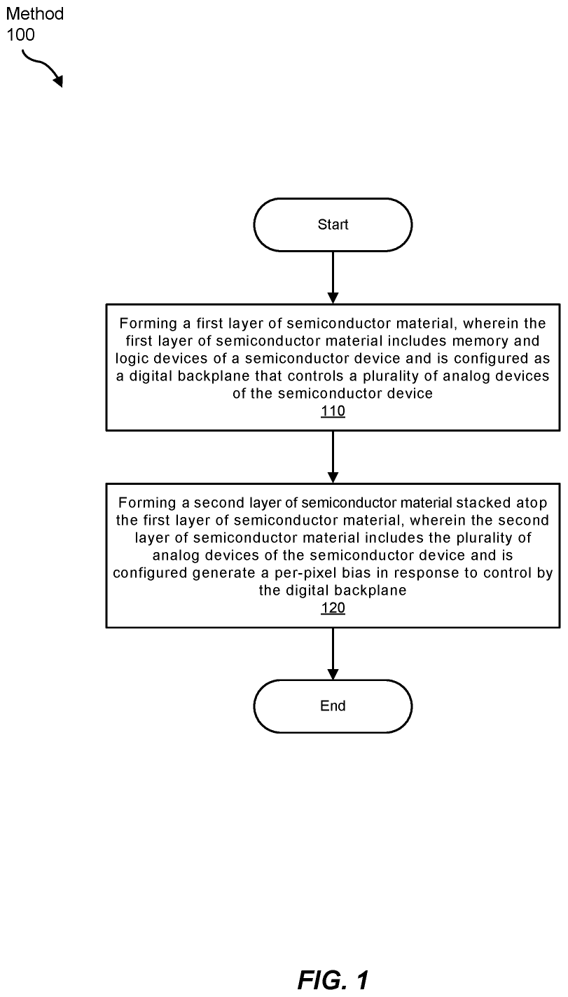

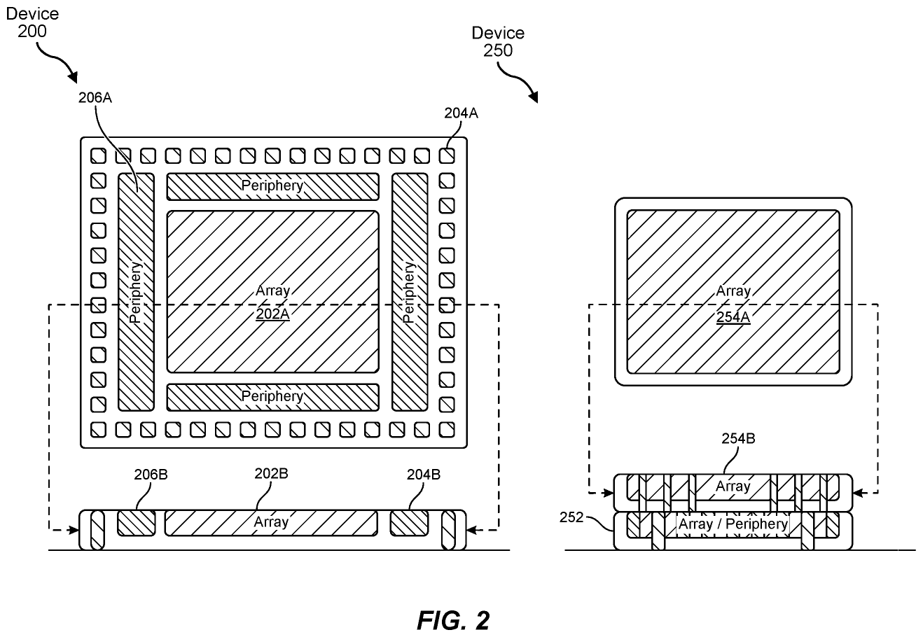

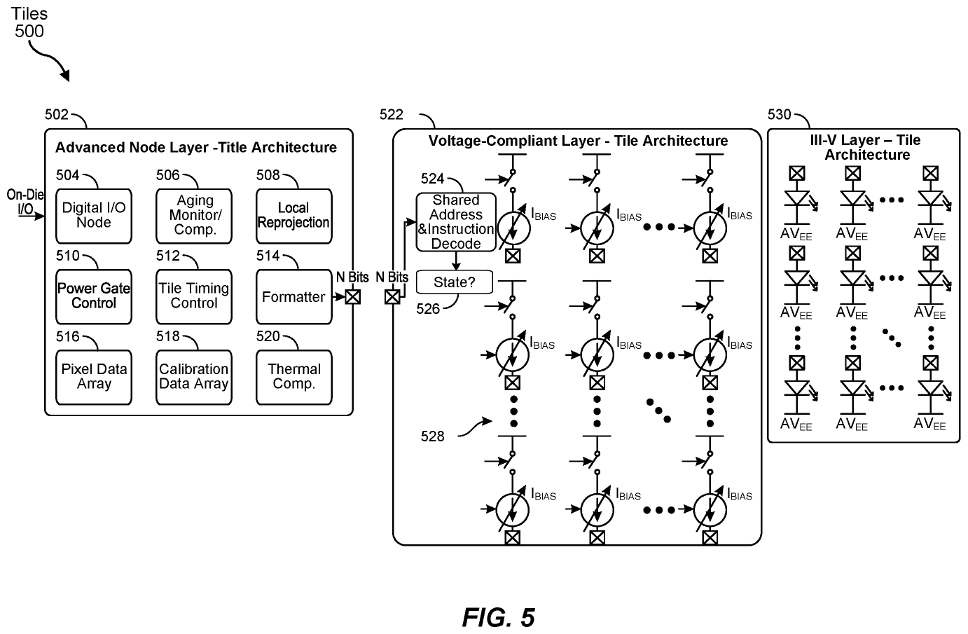

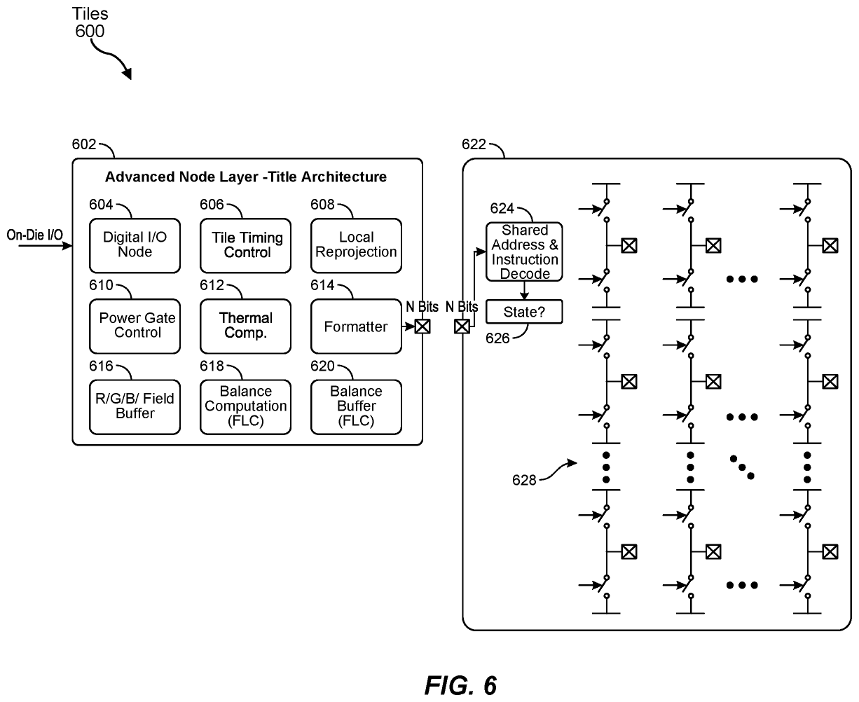

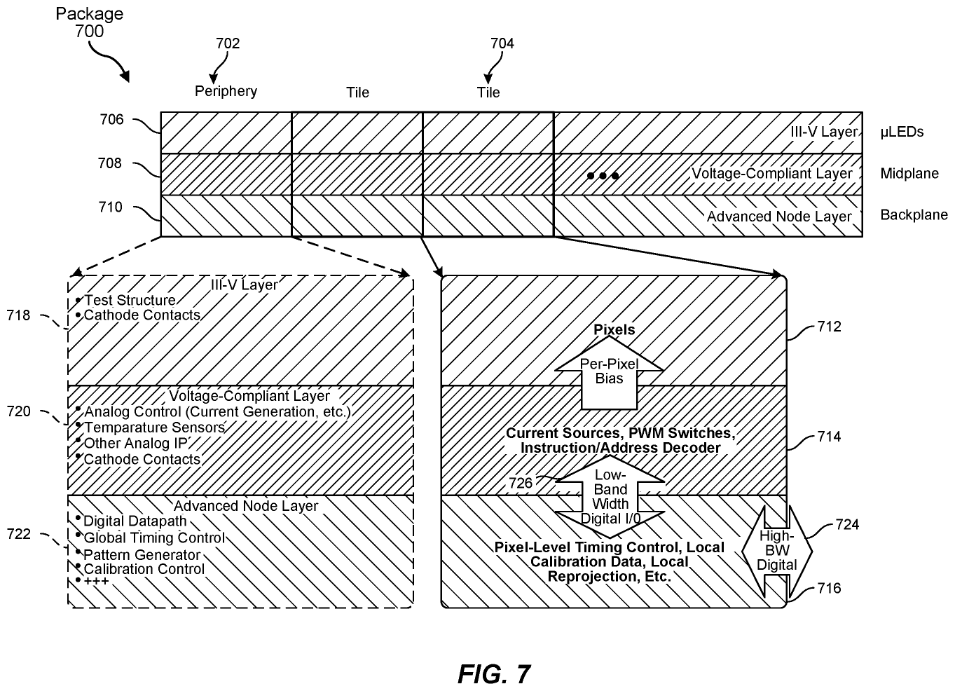

The following will provide, with reference to FIG. 1, detailed descriptions of exemplary methods for pixel disaggregation. Detailed descriptions of exemplary semiconductor devices are also provided with reference to FIGS. 2-4. Additionally, detailed descriptions of exemplary tiles and tile architectures corresponding to portions of layers of semiconductor devices are provided herein with reference to FIGS. 5 and 6. Further, detailed descriptions of exemplary semiconductor device packages are provided herein with reference to FIG. 7.

Referring to FIG. 1, a method 100 for pixel disaggregation may include forming a first layer of semiconductor material. For example, step 110 of method 100 may include forming a first layer of semiconductor material, wherein the first layer of semiconductor material includes memory and logic devices of a semiconductor device and is configured as a digital backplane that controls a plurality of analog devices of the semiconductor device.

The term “semiconductor material,” as used herein, may generally refer to a material which has an electrical conductivity value falling between that of a conductor, such as copper, and an insulator, such as glass. For example, and without limitation, semiconductor materials commonly include silicon, germanium, and/or gallium arsenide.

The term “layer of semiconductor material,” may generally refer to a sheet of semiconductor material. For example, a layer of semiconductor material may include one or more wafers, one or more dies, one or more chips, one or more chips on wafer, etc. Such layers may be distinguished from one another based on their respectively different material compositions, technologies, and/or functions. For example, one layer of semiconductor material may be formed according to a complementary metal-oxide semiconductor (CMOS) technology and another layer of semiconductor material may be formed according to a more advanced technology (e.g., N5, N4, N3, N2, etc.).

The term “memory,” as used herein, may generally refer to an electronic storage device for storing information. For example, and without limitation, memory may include metal-oxide-semiconductor (MOS) memory, volatile memory, non-volatile memory, semi-volatile memory, read only memory (ROM), random access memory (RAM), static random access memory (SRAM), dynamic random access memory (DRAM), etc.

The term “logic devices,” as used herein, may generally refer to a semiconductor device circuit element that is not a memory device and that performs a logical operation on an input signal. For example, and without limitation, logic devices may include microcontrollers, microprocessors, application processors, sensors, or other circuitry configured to perform digital data communication, global timing control, pattern generation, calibration control, pixel-level timing control, and/or local reprojection.

The term “semiconductor device,” as used herein, may generally refer to an electronic component that relies on the electronic properties of a semiconductor material for its function. For example, and without limitation, semiconductor devices may include display devices or portions thereof. Nonlimiting examples of such display devices may include a liquid crystal display (LCD), a light emitting diode (LED) display, a liquid crystal on silicon (LCoS) display, a micro LED (uLED) display, an organic LED (OLED) display, a micro (uOLED) display, a laser diode display, etc.

The term “digital backplane,” as used herein, may generally refer to a group of electrical connectors arranged in parallel with one another and configured to control circuit elements stacked on top of the digital backplane, for example, in a voltage-compliant layer. For example, and without limitation, a digital backplane may correspond to a layer of a semiconductor device that includes memory and logic devices that supply power to another layer of the semiconductor device that includes analog devices. A digital backplane may or may not provide power to the voltage-compliant layer.

The term “analog devices,” as used herein, may generally refer to analog machines, analog media, and/or one or more combinations of analog machines and analog media that have the ability to record, measure, broadcast, and/or reproduce continuous data. For example, and without limitation, analog devices may include analog controllers, temperature sensors, cathode contacts, current sources, pulse width modulation switches, and/or instruction/address decoders.

Method 100 may perform step 110 in various ways. For example, the memory and logic devices may be configured to perform digital data communication, global timing control, pattern generation, calibration control, pixel-level timing control, local calibration data storage, and/or local reprojection. Additionally or alternatively, the first layer may be organized into a tile layout including a periphery adjacent to (e.g., surrounding) inner tiles. In some of these implementations, the periphery may contain a first subset of the memory and logic devices that are configured to perform digital data communication, global timing control, pattern generation, and/or calibration control. Alternatively or additionally, the inner tiles may contain a second subset of the memory and logic devices that may be configured to perform pixel-level timing control, local calibration data storage, and/or local reprojection.

Method 100 also may include forming a second layer of semiconductor material. For example, step 120 of method 100 may include forming a second layer of semiconductor material stacked atop the first layer of semiconductor material, wherein the second layer of semiconductor material includes the plurality of analog devices of the semiconductor device and is configured to generate a per-pixel bias in response to control by the digital backplane.

The term “pixel,” as used herein, may generally refer to an addressable element of a display device. For example, and without limitation, pixels may include smallest addressable elements of a liquid crystal display (LCD), a light emitting diode (LED) display, a liquid crystal on silicon (LCoS) display, a micro LED (uLED) display, an organic LED (OLED) display, a micro (uOLED) display, a laser diode display, etc.

The term “bias,” as used herein, may generally refer to a current and/or voltage that is applied to a circuit to cause it to behave in a predictable manner. For example, and without limitation, bias may refer to a current and/or voltage that creates a potential difference across an LCD, an LED, a LCOS, a uLED, an OLED, a uOLED, a laser diode, etc.

Method 100 may perform step 120 in various ways. For example, the plurality of analog devices may include analog controllers, temperature sensors, cathode contacts, current sources, pulse width modulation switches, and/or instruction/address decoders. Additionally or alternatively, the second layer may be organized into a tile layout including a periphery adjacent to (e.g., surrounding) inner tiles. In some of these implementations, the periphery may contain a first subset of the plurality of analog devices that includes analog controllers, temperature sensors, and/or cathode contacts. Additionally or alternatively, the inner tiles may contain a second subset of the plurality of analog devices that includes current sources, pulse width modulation switches, and/or instruction/address decoders.

In some implementations, method 100 may further include forming a pixel layer. For example, step 120 of method 100 may include forming a pixel layer stacked atop the second layer, wherein the pixel layer includes pixels that receive the per-pixel bias from the second layer. Additionally or alternatively, the pixel layer may be organized into a tile layout including a periphery adjacent to (e.g., surrounding) inner tiles. In some of these implementations, the periphery may contain test structures and/or cathode contacts. Additionally or alternatively, the inner tiles may contain the pixels.

Referring to FIG. 2, a semiconductor device 200 may have a pixel array 202A and 202B surrounded by a bezel corresponding to a border between the pixel array 202A and 202B and a computing device. Circuit elements of the device 200 that may be located in the bezel area may include various devices, such as memory, logic devices, and/or analog devices. Example memory and logic devices may be configured to perform digital data communication, global timing control, pattern generation, calibration control, pixel-level timing control, local calibration data storage, and/or local reprojection. Example analog devices may include cathode contacts 204A and 204B, analog controllers, temperature sensors, current sources, pulse width modulation switches, and/or instruction/address decoders. One or more of these various devices may be located in a periphery 206A and 206B of the bezel.

In contrast to device 200, semiconductor device 250 implements 3D stacking of semiconductor layers and positions one or more of the circuit elements of the device 250 in one or more layers of semiconductor material 252 located beneath a pixel array 254A and 254B of the device 250. This design may improve optical form factor and reduce or eliminate a bezel of the device, thus improving optical performance of the semiconductor device 250 and reducing the area of the semiconductor device 250. Additionally, local translation may be improved by providing additional compute capability in a backplane, thus achieving high-frequency translation of objects based on eye position. Also, optical performance may be improved by providing a pulse-based, high duty cycle (e.g., 10 kilohertz) display and/or by achieving improved pixel performance, such as higher bit depth, improved current source accuracy, and/or additional calibration points for temperature, aging, etc. Further, negative supply rails for common-cathode configuration may be eliminated. Further, a solution for green-blue display applications may be achieved. Finally, the 3-D stacking implementation may achieve pixel pitches of less than two micrometers.

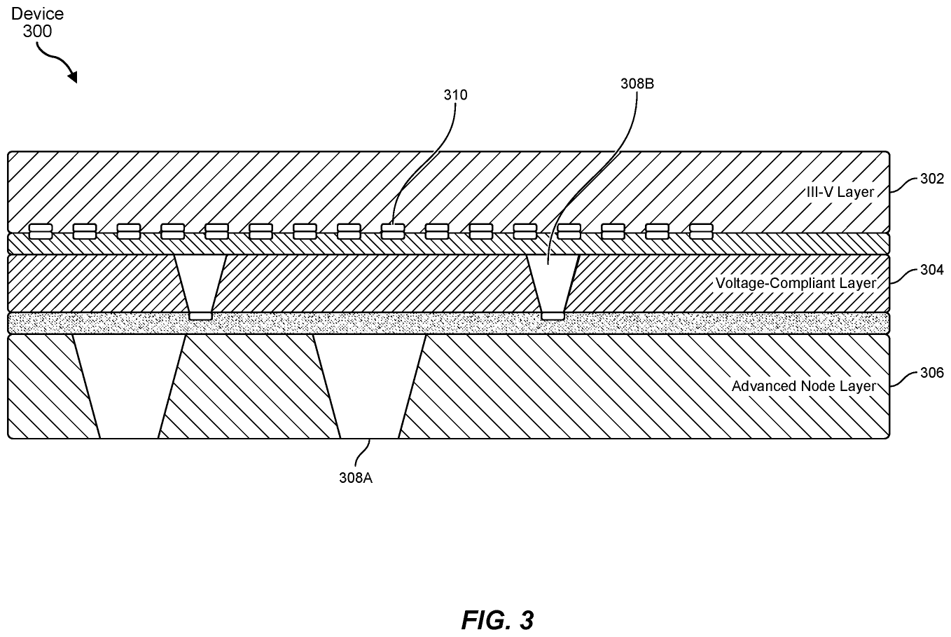

Referring to FIG. 3, semiconductor device 300 demonstrates an example of 3D stacking implemented with a semiconductor compound pixel layer 302. For example, compound pixel layer 302 may correspond to a III-V layer (e.g., a compound such as gallium and nitride (GaN) or gallium and arsenide (GaAs)). Additionally, compound pixel layer 302 may contain various types of pixels, such as LEDs, uLEDs, OLEDs, HOLEDs, etc. Also, compound pixel layer 302 may be stacked atop a middle layer 304 that is stacked atop a bottom layer 306. Further, middle layer 304 may correspond to a voltage-compliant (e.g., CMOS) layer and bottom layer 306 may correspond to an advanced node (e.g., CMOS, N5, N4, N3, N2, etc.) layer constructed according to a more advance technological process compared to that of the middle layer 304. Further, the pixel layer 302, middle layer 304, and bottom layer 306 may be stacked face-to-face, face-to-back, or combinations thereof. Power and/or data signals may be transferred between layers by through silicon vias 308A and 308B, hybrid bonds 310, direct bonding, combinations thereof, etc. Further, the compound pixel layer 302, middle layer 304, and bottom layer 306 may be formed by wafer-on-wafer process, chip-on-wafer process, combinations thereof, etc. Thus, any of the compound pixel layer 302, middle layer 304, and/or bottom layer 306 may correspond to wafers, dies, or any other structure implemented with 3D stacking.

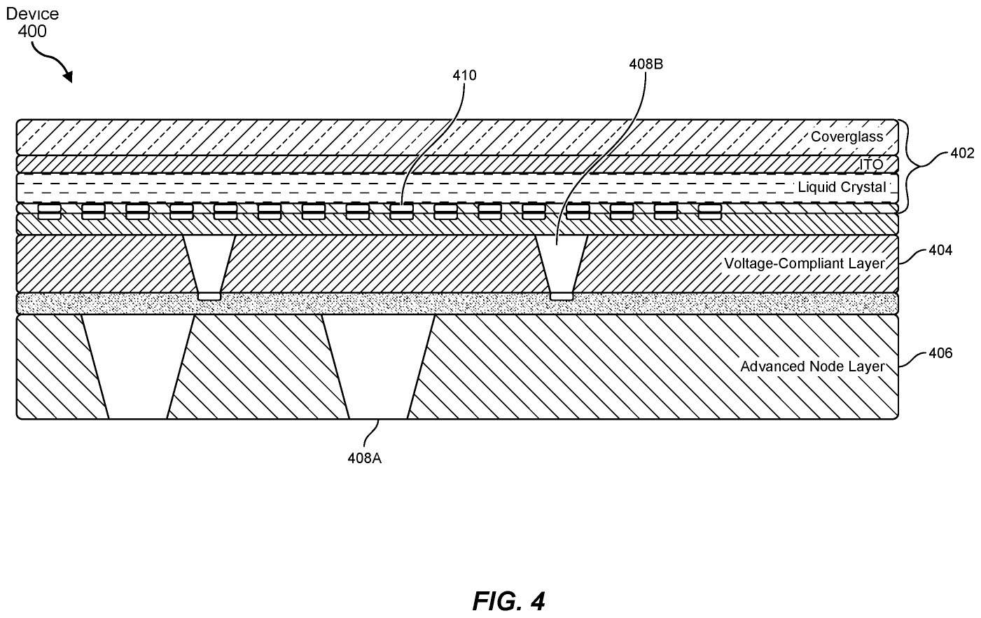

Referring to FIG. 4, semiconductor device 400 demonstrates an example of 3D stacking implemented with an LCD pixel layer 402. For example, LCD pixel layer 402 may include layers of aluminum, liquid crystal, indium tin oxide, and coverglass. Additionally, LCD pixel layer 402 may contain various types of pixels, such as LCDs, LCOS, etc. Also, LCD pixel layer 402 may be stacked atop a middle layer 404 that is stacked atop a bottom layer 406. Further, middle layer 404 may correspond to a voltage-compliant (e.g., CMOS) layer and bottom layer 406 may correspond to an advanced node (e.g., CMOS, N5, N4, N3, N2, etc.) layer constructed according to a more advance technological process compared to that of the middle layer 404. Further, the pixel layer 402, middle layer 404, and bottom layer 406 may be stacked face-to-face, face-to-back, or combinations thereof. Power and/or data signals may be transferred between layers 402-404 by through silicon vias 408A and 408B, hybrid bonds 410, direct bonding, combinations thereof, etc. Further, the LCD pixel layer 402, middle layer 404, and bottom layer 406 may be formed by wafer-on-wafer process, chip-on wafer process, combinations thereof, etc. Thus, any of the LCD pixel layer 402, middle layer 404, and/or bottom layer 406 may correspond to wafers, dies, or any other structure implemented with 3D stacking.

Referring to FIG. 5, portions of layers of the semiconductor devices disclosed herein may be configured as inner tiles 500. For example, a bottom layer (e.g., advanced node (e.g., CMOS, N5, N4, N3, N2, etc.)) may be configured with a tile architecture 502 containing various digital circuit elements (e.g., memory and logic devices) of an integrated circuit of the semiconductor device. Additionally, a middle layer (e.g., voltage-compliant (e.g., CMOS)) may be configured with a tile architecture 522 containing various analog devices of the integrated circuit of the semiconductor device. Also, a pixel layer (e.g., III-V) may be configured with a tile architecture 530 in which one or more tiles contain pixels of a pixel array. In this context, an individual tile may include a portion of the pixel layer stacked atop a portion of the middle layer that is stacked atop a portion of the bottom layer. In operation, the portion of pixel layer within a tile may receive a per-pixel bias from a corresponding portion of middle layer within that tile, which may produce the per-pixel bias in response to control by a corresponding portion of the bottom layer within that tile.

Tile architecture 502 of the bottom layer may include various types of digital circuit elements configured to perform various functions. Example digital circuit elements may include, without limitation, a digital input/output node 504, an aging monitoring and compensation circuit 506, a local reprojection circuit 508, a power gate control circuit 510, a tile timing control circuit 512, a formatter 514, a pixel data array 516, a calibration data array 518, and/or a thermal compensation circuit 520.

Tile architecture 522 of the middle layer may include various types of analog circuit elements. Example analog circuit elements may include, without limitation, a shared address and instruction decode circuit 524, an analog state machine 526, and/or an array 528 of bias sources coupled with pulse width modulation switches. Tile architecture 530 of the pixel layer includes the aforementioned pixel array and may also include one or more other circuit elements of the integrated circuit of the semiconductor device.

Referring to FIG. 6, portions of layers of the semiconductor devices disclosed herein may be configured as inner tiles 600. For example, a bottom layer (e.g., advanced node (e.g., CMOS, N5, N4, N3, N2, etc.)) may be configured with a tile architecture 602 containing various digital circuit elements (e.g., memory and logic devices) of an integrated circuit of the semiconductor device. Additionally, a middle layer (e.g., voltage-compliant (e.g., CMOS)) may be configured with a tile architecture 622 containing various analog devices of the integrated circuit of the semiconductor device. Also, a pixel layer (e.g., LCD, LCOS, etc.) may be configured with a tile architecture in which one or more tiles contain pixels of a pixel array. In this context, an individual tile may include a portion of the pixel layer stacked atop a portion of the middle layer that is stacked atop a portion of the bottom layer. In operation, the portion of pixel layer within a tile may receive a per-pixel bias from a corresponding portion of middle layer within that tile, which may produce the per-pixel bias in response to control by a corresponding portion of the bottom layer within that tile.

Tile architecture 602 of the bottom layer may include various types of digital circuit elements configured to perform various functions. Example digital circuit elements may include, without limitation, a digital input/output node 604, a tile timing control circuit 606, a local reprojection circuit 608, a power gate control circuit 610, a thermal compensation circuit 612, a formatter 614, an R/G/B field buffer 616, a balance computation circuit 618, and/or a balance buffer circuit 620.

Tile architecture 622 of the middle layer may include various types of analog circuit elements. Example analog circuit elements may include, without limitation, a shared address and instruction decode circuit 624, an analog state machine 626, and/or an array 628 of switched current sources. A tile architecture of the pixel layer may include the aforementioned pixel array and may also include one or more other circuit elements of the integrated circuit of the semiconductor device.

Referring to FIG. 7, a semiconductor device package 700 may include a periphery 702 adjacent to (e.g., surrounding) inner tiles 704 having the tile architectures described herein with reference to FIG. 5. In one example, a pixel layer 706 may correspond to a compound pixel layer (e.g., III-V) that includes an array of pixels corresponding to uLEDs. In other examples, the pixel layer 706 may correspond to an LCD pixel layer. Additionally, one or more of the inner tiles 704 may include a portion 712 of the pixel layer stacked atop a portion 714 of the middle layer 708 that is stacked atop a portion 716 of the bottom layer 710. Also, the periphery 702 may include another portion 718 of the pixel layer 706 stacked atop another portion 720 of the middle layer 708 that is stacked atop another portion 722 of the bottom layer 710.

Within a particular one of the inner tiles 704, the portion 716 of the bottom layer 710 may be configured as a digital backplane that controls the tile, and the portion 714 of the middle layer 708 may be configured as a midplane corresponding to an analog chip that responds to specific events from the digital backplane within that tile. Additionally, the portion 716 of the bottom layer 710 may be configured to communicate with other portions of the bottom layer 710 of other inner tiles via a high bandwidth digital data path 724. Also, the portion 716 of the bottom layer 710 within the tile may be configured to communicate with the portion 714 of the middle layer 708 within the tile via a low-bandwidth digital input/output data path 726 that is lower-bandwidth compared to the high-bandwidth digital data path 724. In this way, digital circuit elements (e.g., pixel level timing control, local calibration data, local reprojection, etc.) of the portion 716 of the bottom layer 710 of a tile may control analog circuit elements (e.g., current sources, pulse-width modulation switches, an instruction address decoder, etc.) of the portion 714 of the middle layer 708 of the tile, which may generate a per-pixel bias for the portion 712 of the pixel layer 706 of the tile.

Within the periphery 702, the other portion 722 of the bottom layer 710 may include digital circuit elements (e.g., a digital data path, global timing control, a pattern generator, calibration control, etc.) that form part of the digital backplane. Additionally, the other portion 720 within the periphery 702 may include analog circuit elements (e.g., analog control (e.g., current generation, etc.) temperature sensors, cathode contacts, other analog circuitry, etc.) that form part of the midplane corresponding to the analog chip. Also, the other portion 718 within the periphery 702 may include additional circuit elements (e.g., test structures, cathode contacts, etc.) that form part of the integrated circuit of the semiconductor device. In other implementations, one or more circuit elements contained in the periphery 702 may be integrated within the inner tiles 704.

As set forth above, the disclosed systems and methods may implement pixel disaggregation by, for example, stacking layers of semiconductor material and relocating elements (e.g., memory, logic, and/or analog devices) of a semiconductor device that would otherwise occupy a periphery (e.g., bezel) of the semiconductor device to one of the layers, both reducing an area and improving performance of the semiconductor device. In one example, a first layer of semiconductor material may include memory and logic devices of the semiconductor device and be configured as a digital backplane that controls a plurality of analog devices of the semiconductor device. In this example, a second layer of semiconductor material may be stacked atop the first layer of semiconductor material, and the second layer of semiconductor material may include the plurality of analog devices of the semiconductor device and be configured to generate a per-pixel bias in response to control by the digital backplane.

The disclosed systems and methods may yield numerous benefits. For example, optical form factor may be improved by relocating analog devices to a stacked layer of a semiconductor device, thus removing a bezel of the device, which improves optical performance of the semiconductor device and reduces the area of the semiconductor device. Additionally, 3D stacking may yield shorter power and/or signal pathways that experience reduced current drop. Also, 3D stacking that disaggregates analog and digital circuit elements into different semiconductor layers allows a layer containing the digital elements to be constructed according to a more advanced technology (e.g., smaller circuit elements) compared to another layer containing the analog circuit elements, thus achieving additional compute capability for the digital circuit elements without incurring increased costs for the analog circuit elements. As a result, local translation may be improved by providing additional compute capability in a backplane, thus achieving high-frequency translation of objects based on eye position. Further, optical performance may be improved by providing a pulse-based, high duty cycle (e.g., 10 kilohertz) display and/or by achieving improved pixel performance, such as higher bit depth, improved current source accuracy, and/or additional calibration points for temperature, aging, etc. Further, the disclosed systems and methods offer an option to eliminate negative supply rails for common-cathode configuration and/or provide a potential solution for green-blue display applications. Finally, the 3-D stacking implementation may achieve pixel pitches of less than two micrometers.

Embodiments of the present disclosure may include or be implemented in conjunction with various types of artificial reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

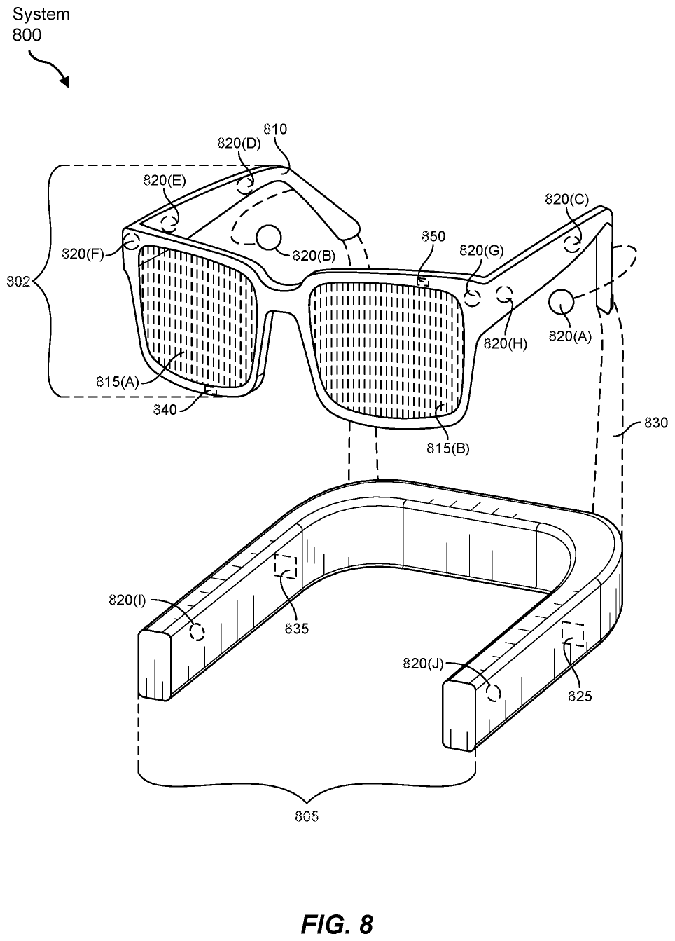

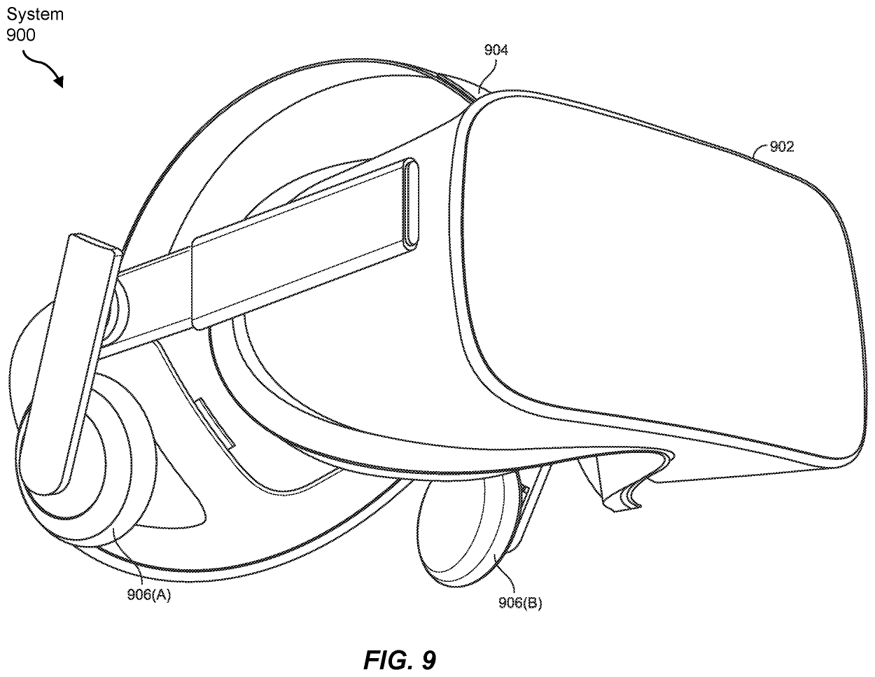

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 800 in FIG. 8) or that visually immerses a user in an artificial reality (such as, e.g., virtual-reality system 900 in FIG. 9). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 8, augmented-reality system 800 may include an eyewear device 802 with a frame 810 configured to hold a left display device 815(A) and a right display device 815(B) in front of a user's eyes. Display devices 815(A) and 815(B) may act together or independently to present an image or series of images to a user. While augmented-reality system 800 includes two displays, embodiments of this disclosure may be implemented in augmented-reality systems with a single NED or more than two NEDs.

In some embodiments, augmented-reality system 800 may include one or more sensors, such as sensor 840. Sensor 840 may generate measurement signals in response to motion of augmented-reality system 800 and may be located on substantially any portion of frame 810. Sensor 840 may represent one or more of a variety of different sensing mechanisms, such as a position sensor, an inertial measurement unit (IMU), a depth camera assembly, a structured light emitter and/or detector, or any combination thereof. In some embodiments, augmented-reality system 800 may or may not include sensor 840 or may include more than one sensor. In embodiments in which sensor 840 includes an IMU, the IMU may generate calibration data based on measurement signals from sensor 840. Examples of sensor 840 may include, without limitation, accelerometers, gyroscopes, magnetometers, other suitable types of sensors that detect motion, sensors used for error correction of the IMU, or some combination thereof.

In some examples, augmented-reality system 800 may also include a microphone array with a plurality of acoustic transducers 820(A)-820(J), referred to collectively as acoustic transducers 820. Acoustic transducers 820 may represent transducers that detect air pressure variations induced by sound waves. Each acoustic transducer 820 may be configured to detect sound and convert the detected sound into an electronic format (e.g., an analog or digital format). The microphone array in FIG. 8 may include, for example, ten acoustic transducers: 820(A) and 820(B), which may be designed to be placed inside a corresponding ear of the user, acoustic transducers 820(C), 820(D), 820(E), 820(F), 820(G), and 820(H), which may be positioned at various locations on frame 810, and/or acoustic transducers 820(1) and 820(J), which may be positioned on a corresponding neckband 805.

In some embodiments, one or more of acoustic transducers 820(A)-(J) may be used as output transducers (e.g., speakers). For example, acoustic transducers 820(A) and/or 820(B) may be earbuds or any other suitable type of headphone or speaker.

The configuration of acoustic transducers 820 of the microphone array may vary. While augmented-reality system 800 is shown in FIG. 8 as having ten acoustic transducers 820, the number of acoustic transducers 820 may be greater or less than ten. In some embodiments, using higher numbers of acoustic transducers 820 may increase the amount of audio information collected and/or the sensitivity and accuracy of the audio information. In contrast, using a lower number of acoustic transducers 820 may decrease the computing power required by an associated controller 850 to process the collected audio information. In addition, the position of each acoustic transducer 820 of the microphone array may vary. For example, the position of an acoustic transducer 820 may include a defined position on the user, a defined coordinate on frame 810, an orientation associated with each acoustic transducer 820, or some combination thereof.

Acoustic transducers 820(A) and 820(B) may be positioned on different parts of the user's ear, such as behind the pinna, behind the tragus, and/or within the auricle or fossa. Or, there may be additional acoustic transducers 820 on or surrounding the ear in addition to acoustic transducers 820 inside the ear canal. Having an acoustic transducer 820 positioned next to an ear canal of a user may enable the microphone array to collect information on how sounds arrive at the ear canal. By positioning at least two of acoustic transducers 820 on either side of a user's head (e.g., as binaural microphones), augmented-reality system 800 may simulate binaural hearing and capture a 3D stereo sound field around about a user's head. In some embodiments, acoustic transducers 820(A) and 820(B) may be connected to augmented-reality system 800 via a wired connection 830, and in other embodiments acoustic transducers 820(A) and 820(B) may be connected to augmented-reality system 800 via a wireless connection (e.g., a BLUETOOTH connection). In still other embodiments, acoustic transducers 820(A) and 820(B) may not be used at all in conjunction with augmented-reality system 800.

Acoustic transducers 820 on frame 810 may be positioned in a variety of different ways, including along the length of the temples, across the bridge, above or below display devices 815(A) and 815(B), or some combination thereof. Acoustic transducers 820 may also be oriented such that the microphone array is able to detect sounds in a wide range of directions surrounding the user wearing the augmented-reality system 800. In some embodiments, an optimization process may be performed during manufacturing of augmented-reality system 800 to determine relative positioning of each acoustic transducer 820 in the microphone array.

In some examples, augmented-reality system 800 may include or be connected to an external device (e.g., a paired device), such as neckband 805. Neckband 805 generally represents any type or form of paired device. Thus, the following discussion of neckband 805 may also apply to various other paired devices, such as charging cases, smart watches, smart phones, wrist bands, other wearable devices, hand-held controllers, tablet computers, laptop computers, other external compute devices, etc.

As shown, neckband 805 may be coupled to eyewear device 802 via one or more connectors. The connectors may be wired or wireless and may include electrical and/or non-electrical (e.g., structural) components. In some cases, eyewear device 802 and neckband 805 may operate independently without any wired or wireless connection between them. While FIG. 8 illustrates the components of eyewear device 802 and neckband 805 in example locations on eyewear device 802 and neckband 805, the components may be located elsewhere and/or distributed differently on eyewear device 802 and/or neckband 805. In some embodiments, the components of eyewear device 802 and neckband 805 may be located on one or more additional peripheral devices paired with eyewear device 802, neckband 805, or some combination thereof.

Pairing external devices, such as neckband 805, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 800 may be provided by a paired device or shared between a paired device and an eyewear device, thus reducing the weight, heat profile, and form factor of the eyewear device overall while still retaining desired functionality. For example, neckband 805 may allow components that would otherwise be included on an eyewear device to be included in neckband 805 since users may tolerate a heavier weight load on their shoulders than they would tolerate on their heads. Neckband 805 may also have a larger surface area over which to diffuse and disperse heat to the ambient environment. Thus, neckband 805 may allow for greater battery and computation capacity than might otherwise have been possible on a stand-alone eyewear device. Since weight carried in neckband 805 may be less invasive to a user than weight carried in eyewear device 802, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 805 may be communicatively coupled with eyewear device 802 and/or to other devices. These other devices may provide certain functions (e.g., tracking, localizing, depth mapping, processing, storage, etc.) to augmented-reality system 800. In the embodiment of FIG. 8, neckband 805 may include two acoustic transducers (e.g., 820(I) and 820(J)) that are part of the microphone array (or potentially form their own microphone subarray). Neckband 805 may also include a controller 825 and a power source 835.

Acoustic transducers 820(1) and 820(J) of neckband 805 may be configured to detect sound and convert the detected sound into an electronic format (analog or digital). In the embodiment of FIG. 8, acoustic transducers 820(I) and 820(J) may be positioned on neckband 805, thereby increasing the distance between the neckband acoustic transducers 820(1) and 820(J) and other acoustic transducers 820 positioned on eyewear device 802. In some cases, increasing the distance between acoustic transducers 820 of the microphone array may improve the accuracy of beamforming performed via the microphone array. For example, if a sound is detected by acoustic transducers 820(C) and 820(D) and the distance between acoustic transducers 820(C) and 820(D) is greater than, e.g., the distance between acoustic transducers 820(D) and 820(E), the determined source location of the detected sound may be more accurate than if the sound had been detected by acoustic transducers 820(D) and 820(E).

Controller 825 of neckband 805 may process information generated by the sensors on neckband 805 and/or augmented-reality system 800. For example, controller 825 may process information from the microphone array that describes sounds detected by the microphone array. For each detected sound, controller 825 may perform a direction-of-arrival (DOA) estimation to estimate a direction from which the detected sound arrived at the microphone array. As the microphone array detects sounds, controller 825 may populate an audio data set with the information. In embodiments in which augmented-reality system 800 includes an inertial measurement unit, controller 825 may compute all inertial and spatial calculations from the IMU located on eyewear device 802. A connector may convey information between augmented-reality system 800 and neckband 805 and between augmented-reality system 800 and controller 825. The information may be in the form of optical data, electrical data, wireless data, or any other transmittable data form. Moving the processing of information generated by augmented-reality system 800 to neckband 805 may reduce weight and heat in eyewear device 802, making it more comfortable to the user.

Power source 835 in neckband 805 may provide power to eyewear device 802 and/or to neckband 805. Power source 835 may include, without limitation, lithium-ion batteries, lithium-polymer batteries, primary lithium batteries, alkaline batteries, or any other form of power storage. In some cases, power source 835 may be a wired power source. Including power source 835 on neckband 805 instead of on eyewear device 802 may help better distribute the weight and heat generated by power source 835.

As noted, some artificial reality systems may, instead of blending an artificial reality with actual reality, substantially replace one or more of a user's sensory perceptions of the real world with a virtual experience. One example of this type of system is a head-worn display system, such as virtual-reality system 900 in FIG. 9, that mostly or completely covers a user's field of view. Virtual-reality system 900 may include a front rigid body 902 and a band 904 shaped to fit around a user's head. Virtual-reality system 900 may also include output audio transducers 906(A) and 906(B). Furthermore, while not shown in FIG. 9, front rigid body 902 may include one or more electronic elements, including one or more electronic displays, one or more inertial measurement units (IMUs), one or more tracking emitters or detectors, and/or any other suitable device or system for creating an artificial-reality experience.

Artificial reality systems may include a variety of types of visual feedback mechanisms. For example, display devices in augmented-reality system 800 and/or virtual-reality system 900 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial reality systems may include a single display screen for both eyes or may provide a display screen for each eye, which may allow for additional flexibility for varifocal adjustments or for correcting a user's refractive error. Some of these artificial reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial reality systems described herein may include one or more projection systems. For example, display devices in augmented-reality system 800 and/or virtual-reality system 900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial reality systems may also be configured with any other suitable type or form of image projection system, such as retinal projectors used in virtual retina displays.

The artificial reality systems described herein may also include various types of computer vision components and subsystems. For example, augmented-reality system 800 and/or virtual-reality system 900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial reality system may process data from one or more of these sensors to identify a location of a user, to map the real world, to provide a user with context about real-world surroundings, and/or to perform a variety of other functions.

The artificial reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A semiconductor device, comprising:
a first layer of semiconductor material, wherein the first layer of semiconductor material includes memory and logic devices of the semiconductor device and is configured as a digital backplane that controls a plurality of analog devices of the semiconductor device; and
a second layer of semiconductor material stacked atop the first layer of semiconductor material, wherein the second layer of semiconductor material includes the plurality of analog devices of the semiconductor device and is configured generate a per-pixel bias in response to control by the digital backplane.

2. The semiconductor device of claim 1, wherein the memory and logic devices are configured to perform at least one of digital data communication, global timing control, pattern generation, calibration control, pixel-level timing control, local calibration data storage, or local reprojection.

3. The semiconductor device of claim 2, wherein:
the first layer is organized into a tile layout including a periphery adjacent to inner tiles;
the periphery contains a first subset of the memory and logic devices that are configured to perform at least one of digital data communication, global timing control, pattern generation, or calibration control; and
the inner tiles contain a second subset of the memory and logic devices that are configured to perform at least one of pixel-level timing control, local calibration data storage, or local reprojection.

4. The semiconductor device of claim 1, wherein the plurality of analog devices includes at least one of analog controllers, temperature sensors, cathode contacts, current sources, pulse width modulation switches, or instruction/address decoders.

5. The semiconductor device of claim 4, wherein:
the second layer is organized into a tile layout including a periphery adjacent to inner tiles;
the periphery contains a first subset of the plurality of analog devices that includes at least one of analog controllers, temperature sensors, or cathode contacts; and
the inner tiles contain a second subset of the plurality of analog devices that includes at least one of current sources, pulse width modulation switches, or instruction/address decoders.

6. The semiconductor device of claim 1, further comprising:
a pixel layer stacked atop the second layer, wherein the pixel layer includes pixels that receive the per-pixel bias from the second layer.

7. The semiconductor device of claim 6, wherein:
the pixel layer is organized into a tile layout including a periphery adjacent to inner tiles;
the periphery contains at least one of test structures and cathode contacts; and
the inner tiles contain the pixels.

8. A method, comprising:
forming a first layer of semiconductor material, wherein the first layer of semiconductor material includes memory and logic devices of a semiconductor device and is configured as a digital backplane that controls a plurality of analog devices of the semiconductor device; and
forming a second layer of semiconductor material stacked atop the first layer of semiconductor material, wherein the second layer of semiconductor material includes the plurality of analog devices of the semiconductor device and is configured generate a per-pixel bias in response to control by the digital backplane.

9. The method of claim 8, wherein the memory and logic devices are configured to perform at least one of digital data communication, global timing control, pattern generation, calibration control, pixel-level timing control, local calibration data storage, or local reprojection.

10. The method of claim 9, wherein:
the first layer is organized into a tile layout including a periphery adjacent to inner tiles;
the periphery contains a first subset of the memory and logic devices that are configured to perform at least one of digital data communication, global timing control, pattern generation, or calibration control; and
the inner tiles contain a second subset of the memory and logic devices that are configured to perform at least one of pixel-level timing control, local calibration data storage, or local reprojection.

11. The method of claim 8, wherein the plurality of analog devices includes at least one of analog controllers, temperature sensors, cathode contacts, current sources, pulse width modulation switches, or instruction/address decoders.

12. The method of claim 11, wherein:
the second layer is organized into a tile layout including a periphery adjacent to inner tiles;
the periphery contains a first subset of the plurality of analog devices that includes at least one of analog controllers, temperature sensors, or cathode contacts; and
the inner tiles contain a second subset of the plurality of analog devices that includes at least one of current sources, pulse width modulation switches, or instruction/address decoders.

13. The method of claim 8, further comprising:
forming a pixel layer stacked atop the second layer, wherein the pixel layer includes pixels that receive the per-pixel bias from the second layer.

14. The method of claim 13, wherein:
the pixel layer is organized into a tile layout including a periphery adjacent to inner tiles;
the periphery contains at least one of test structures and cathode contacts; and
the inner tiles contain the pixels.

15. A semiconductor device package, comprising:
a bottom layer of semiconductor material configured as a digital backplane that controls a plurality of analog devices of a semiconductor device of the semiconductor device package;
a middle layer of semiconductor material stacked atop the bottom layer of semiconductor material, wherein the middle layer of semiconductor material is configured generate a per-pixel bias in response to control by the digital backplane; and
a pixel layer stacked atop the middle layer, wherein the pixel layer includes pixels that receive the per-pixel bias from the middle layer.

16. The semiconductor device package of claim 15, wherein the bottom layer, the middle layer, and the pixel layer are organized into a tile layout.

17. The semiconductor device package of claim 16, wherein the middle layer is configured, within a tile of the tile layout, to respond to control, within the tile, by the digital backplane.

18. The semiconductor device package of claim 15, wherein the bottom layer includes memory and logic devices that are configured to perform at least one of digital data communication, global timing control, pattern generation, calibration control, pixel-level timing control, local calibration data storage, or local reprojection.

19. The semiconductor device package of claim 15, wherein the middle layer includes analog devices that correspond to at least one of analog controllers, temperature sensors, cathode contacts, current sources, pulse width modulation switches, or instruction/address decoders.

20. The semiconductor device package of claim 15, wherein the pixel layer further includes at least one of cathode contacts or test structures.
